(19) United States
(12) Patent Application Publication
(10) Pub. No.: US 2026/0130066 A1
(43) Pub. Date: May 7, 2026

(54) DISPLAY DEVICE

(71) Applicant: LG Display Co., Ltd., Seoul (KR)

(72) Inventors: Sinchul KANG, Gimpo-si (KR); GyuHo LEE, Seoul (KR); Miyeon SEO, Seoul (KR); Sungjin PARK, Seoul (KR)

(73) Assignee: LG Display Co., Ltd., Seoul (KR)

(21) Appl. No.: 19/345,691

(22) Filed: Sep. 30, 2025

(30) Foreign Application Priority Data
Nov. 4, 2024 (KR) 10-2024-0154272

(51) Int. Cl. H10K 59/124; H10K 59/122; H10K 59/127; H10K 59/131; H10K 102/00

(52) U.S. Cl. CPC H10K 59/124; H10K 59/122; H10K 59/127; H10K 59/131; H10K 2102/311

(57) ABSTRACT

A display device includes an active area having a plurality of sub pixels, a first non-active area adjacent to the active area, a bending area extending from the first non-active area, and a second non-active area extending from the bending area. A first substrate is disposed in the active area and the first non-active area, and a second substrate is disposed in the second non-active area and spaced apart from the first substrate. A plurality of insulating layers is disposed on the first substrate and the second substrate and extends to the bending area. At least a portion of the insulating layers includes a plurality of first holes disposed along a bending direction in the bending area. The holes reduce stress concentration and suppress crack formation and propagation during bending, thereby enhancing the reliability of the display device.

### CROSS-REFERENCE TO RELATED APPLICATIONS

This application claims the priority of Korean Patent Application No. 10-2024-0154272 filed on Nov. 4, 2024, in the Korean Intellectual Property Office, the disclosure of which is incorporated herein by reference.

### BACKGROUND

### Technical Field

The present disclosure relates to a display device, and more particularly, to a display device which suppresses propagation of cracks when it is bent.

### Description of the Related Art

Generally, display devices are widely used as display screens for various electronic devices, such as mobile communication terminals, electronic notebooks, electronic books, portable multimedia players (PMPs), ultra mobile PCs (UMPC), mobile phones, smart phones, tablet PCs (Personal Computers), electronic pads, wearable devices, watch phones, portable information devices, navigation, vehicle control display devices, televisions, notebooks, and monitors.

Recently, display devices which implement a maximum screen by reducing a bezel area in which images are not displayed with the same size of display panel are being studied and developed.

### BRIEF SUMMARY

The disclosed display device introduces a structure for suppressing cracks in flexible panels by strategically integrating a plurality of quadrangular holes in the insulating layers along the bending area. These holes, arranged either continuously or in staggered patterns, relieve stress concentration during bending and prevent the initiation and propagation of cracks. Some embodiments include holes only within the bending region, while others extend the holes into adjacent non-active areas, including regions containing conductive lines and pad units, to protect areas essential for electrical connectivity and mechanical integrity.

The design further incorporates a micro coating layer that fills the holes and is placed above and below the insulating layers. By shifting the neutral plane upward, this layer reduces tensile stress on brittle components, including the conductive lines, thereby lowering the risk of fractures when the panel is bent. The use of ductile conductive materials and optimized substrate geometries, such as inclined sidewalls near the bending regions, further enhances flexibility while preserving durability.

Several embodiments are presented with different hole arrangements, material configurations, and layer compositions to accommodate various manufacturing processes and mechanical requirements. This approach provides flexibility in design while improving bending reliability and extending the operational life of the display device.

Various embodiments of the present disclosure provide a display device which reduces a stress generated in a bending area and improves reliability.

Various embodiments of the present disclosure provide a display device which suppresses generation and propagation of a crack while being bent.

Technical benefits of the present disclosure are not limited to the above-mentioned benefits, and other benefits, which are not mentioned above, can be clearly understood by those skilled in the art from the following descriptions.

According to an aspect of the present disclosure, a display device includes an active area in which a plurality of sub pixels is disposed, a first non-active area which encloses the active area, a bending area which extends from the first non-active area, and a second non-active area which extends from the bending area, the display device includes a first substrate disposed in the active area and the first non-active area, a second substrate which is disposed in the second non-active area and is spaced apart from the first substrate and a plurality of insulating layers which is disposed on the first substrate and the second substrate and extends to the bending area, wherein at least a part of the plurality of insulating layers includes a plurality of first holes disposed along a bending direction in the bending area.

According to another aspect of the present disclosure, a display device a plurality of insulating layers which includes an active area in which a plurality of sub pixels is disposed, a first non-active area which encloses the active area, a bending area which extends from the first non-active area, and a second non-active area which extends from the bending area, a first substrate disposed below the plurality of insulating layers in the active area and the first non-active area, a second substrate which is disposed below the plurality of insulating layers in the second non-active area and is spaced apart from the first substrate, a plurality of first holes which is disposed in at least a part of the plurality of insulating layers along a bending direction in the bending area and a micro coating layer which is disposed above and below the plurality of insulating layers in the bending area and is filled in the plurality of first holes.

Other detailed matters of the exemplary embodiments are included in the detailed description and the drawings.

According to the present disclosure, a stress which is intensively generated in a part of the bending area during the manufacturing process is suppressed and the crack is minimized, thereby improving the reliability.

According to the present disclosure, the crack which is generated in the bending area while being bent is suppressed from propagating to the other area.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary embodiment of the present disclosure;

FIG. 2 is a cross-sectional view of a sub pixel of a display device according to an exemplary embodiment of the present disclosure.

FIG. 3 is a plan view of enlarging areas A and B of FIG. 1;

FIG. 4 is a cross-sectional view taken along C-C′ of FIG. 3;

FIG. 5 is a cross-sectional view taken along D-D′ of FIG. 3;

FIG. 6 is a cross-sectional view of a non-active area of a display device according to another exemplary embodiment of the present disclosure;

FIG. 7 is an enlarged plan view of a display device according to still another exemplary embodiment of the present disclosure;

FIG. 8 is an enlarged plan view of a display device according to still another exemplary embodiment of the present disclosure;

FIG. 9 is an enlarged plan view of a display device according to still another exemplary embodiment of the present disclosure;

FIG. 10 is a cross-sectional view taken along E-E′ of FIG. 9; and

FIG. 11 is a cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately”or “directly”.

When explaining temporal relationships, terms such as “after,” “following,” “subsequent to,” or “before,” etc., may include non-consecutive cases unless terms like “immediately”or “directly”are used.

Terms such as “first,” “second,” etc., are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

The expressions “A fills B” or “A filled in B” are not intended to indicate that A is present in B to the exclusion of all other materials. These expressions are to be interpreted broadly to include, without limitation, situations where A is partially filling, substantially filling, completely filling, or exclusively filling B. Likewise, the expression “B filled with A” is not limited to circumstances where B contains only A. Rather, it encompasses any degree of filling, including partially filled with A, substantially filled with A, completely filled with A, or exclusively filled with A.

As used herein, the term “intersect” is intended to be interpreted broadly and does not require that two elements physically contact or cross at a single point. The term includes, but is not limited to, configurations in which one element overlaps, traverses across, crosses over, is vertically aligned with, or extends over another element in a plan view or a cross-sectional view. The term may also encompass situations where elements are separated by one or more intervening layers, such as insulating films or dielectric structures. Accordingly, “intersect” should be understood to include relative positional arrangements that result in electrical, optical, or spatial alignment, even in the absence of direct physical contact.

The features of various embodiments in the present disclosure may be partially or wholly combined or associated with each other, various technical interlocking and operations are possible, and each embodiment may be implemented independently of each other or may be implemented together in an associated relationship.

Hereinafter, a display apparatus according to exemplary embodiments of the present disclosure will be described in detail with reference to accompanying drawings.

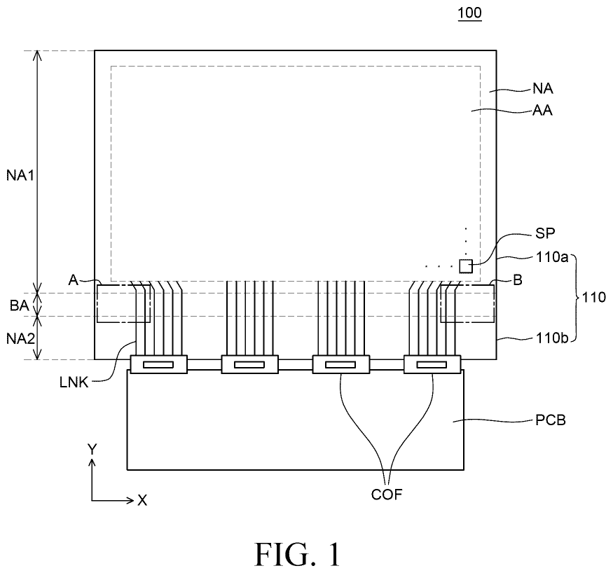

FIG. 1 is a plan view of a display device according to an exemplary embodiment of the present disclosure. For the convenience of description, in FIG. 1, among various components of the display device 100, only a substrate 110, a plurality of flexible films COF, and a printed circuit board PCB are illustrated.

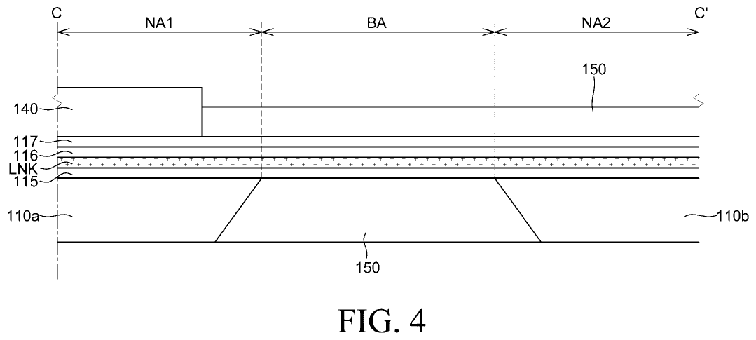

Referring to FIG. 1, the substrate 110 is a component for supporting various components included in the display device 100 and may be formed of an insulating material. For example, the substrate 110 is a glass substrate which is formed of glass. The substrate 110 includes a first substrate 110a and a second substrate 110b. The first substrate 110a and the second substrate 110b will be described in more detail with reference to FIG. 4.

The substrate 110 includes an active area AA, in which a plurality of sub pixels SP actually emitting light through a transistor and a light emitting diode is disposed, and a non-active area NA which encloses an outer periphery of the active area AA.

The active area AA may be an area where a plurality of sub pixels SP is disposed to display images. Each of the plurality of sub pixels SP is an individual unit which emits light and in each of the plurality of sub pixels SP, a light emitting diode and a driving circuit may be formed. For example, in the plurality of sub pixels SP, a light emitting diode for displaying images and a circuit unit for driving the light emitting diode may be disposed. At this time, if the display device 100 is an organic light emitting display device, the light emitting diode may include an organic light emitting diode and when the display device 100 is a liquid crystal display device, the light emitting diode may include a liquid crystal element. The plurality of sub pixels SP may include a red sub pixel, a green sub pixel, a blue sub pixel, and a white sub pixel, but is not limited thereto. The driving circuit may include various transistors, storage capacitors, and wiring lines for driving the plurality of sub pixels SP. For example, the driving circuit may be configured by various components, such as a driving transistor, a switching transistor, a sensing transistor, a storage capacitor, a gate line, and a data line, but is not limited thereto.

In the non-active area NA, a circuit and various wiring lines for driving the display device 100 may be disposed.

The non-active area NA may include a first non-active area NA1 enclosing the active area AA, a bending area BA extending from the first non-active area NA1, and a second non-active area NA2 extending from one side of the bending area BA.

Specifically, the first non-active area NA1 is an area in which an image is not displayed and may be disposed so as to enclose the active area AA. In the first non-active area NA1, various wiring lines and driving IC for driving a plurality of sub pixels disposed in the active area AA are disposed. The first non-active area NA1 in which an image is not displayed may be a bezel area, but exemplary embodiments of the present disclosure are not limited thereto.

A part of the non-active area NA may be bent in a bending direction illustrated by an arrow in FIG. 1. For example, the bending direction refers to a Y-axis direction. An area which is bent as described above may be referred to as a bending area BA. In other words, the bending area BA is a part of the first non-active area NA1 which extends from one side of the non-active area NA and may be an area to be bent.

In the second non-active area NA2 extending from one side of the bending area BA, a pad unit may be disposed. The pad unit may include a plurality of pad electrodes to which an external module is bonded.

The plurality of flexible films COF may be disposed in one end of the substrate 110. The plurality of flexible films COF is films in which various components are disposed on a base film having a ductility to supply a signal to the plurality of sub pixels and a driving circuit and may be electrically connected to the substrate 110. For example, the plurality of flexible films COF may supply a power voltage, a gate control signal, and a data voltage to the plurality of sub pixels and the driving circuit.

In the meantime, a driving IC, such as a data driver IC, may be disposed on the plurality of flexible films COF. The driving IC is a component which processes data for displaying images and a driving signal for processing the data. The driving IC may be disposed in a chip on glass (COG), a chip on film (COF), or a tape carrier package (TCP) manner depending on a mounting method. However, for the convenience of description, it is described that the driving IC is mounted on the plurality of flexible films COF by a chip on film technique, but is not limited thereto. Further, the driving IC may be integrated with the timing controller to be disposed as a single chip. In the meantime, even though it is illustrated that four flexible films COF are disposed in FIG. 1, it is not limited thereto and the number of the plurality of flexible films COF may vary depending on the design, but is not limited thereto.

The printed circuit board PCB is electrically connected to the plurality of flexible films COF. The printed circuit board PCB is a component which supplies signals to the driving IC. Various components may be disposed in the printed circuit board PCB to supply various signals such as a driving signal or a data signal to the driving IC. In the meantime, even though it is illustrated that a plurality of flexible films COF is electrically connected to one printed circuit board PCB in FIG. 1, the present disclosure is not limited thereto and a plurality of flexible films COF may be electrically connected to a plurality of printed circuit boards PCB, respectively. Various wiring lines may be formed on the substrate 110. The wiring line may be disposed in the active area AA of the substrate 110 and may be also disposed in the non-active area NA. Specifically, a link line LNK formed in the non-active area NA is connected to a driving circuit, for example, a gate driver, a data driver, and a timing controller to transmit a signal to the sub pixel.

The link line LNK is formed of a conductive material and may be formed of a conductive material having an excellent ductility to reduce the crack generated at the time of bending the substrate 110. For example, the link line LNK may be formed of a conductive material having excellent ductility, such as gold (Au), silver (Ag), and aluminum (Al) and formed of one of various conductive materials used in the active area AA. The link line LNK may also be configured by molybdenum (Mo), chrome (Cr), titanium (Ti), nickel (Ni), neodymium (Nd), copper (Cu), and an alloy of silver (Ag), and magnesium (Mg). Further, the link line LNK may be configured by a multi-layered structure including various conductive materials and for example, configured by a triple layered structure of titanium (Ti)/aluminum (Al)/titanium (Ti), but the structure of the link line LNK according to the present disclosure is not limited thereto.

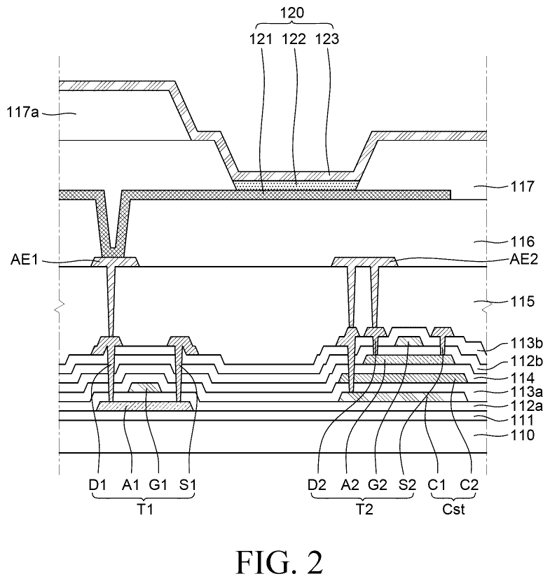

FIG. 2 is a cross-sectional view of a sub pixel of a display device according to an exemplary embodiment of the present disclosure.

Referring to FIG. 2, the display device 100 may include a substrate 110, a first transistor T1, a second transistor T2, a storage capacitor Cst, and a light emitting diode 120.

The substrate 110 serves to support and protect components of the display device 100 disposed thereabove. The substrate 110 may be formed of glass.

A lower buffer layer 111 may be disposed on the substrate 110. The lower buffer layer 111 suppresses permeation of moisture or other impurities through the substrate 110 and may planarize a surface of the substrate 110.

The lower buffer layer 111 is formed by multiple layers to be referred to as a multi buffer layer, but is not limited thereto. The lower buffer layer 111 may be formed by a single layer. For example, the lower buffer layer 111 may be formed by a single layer of any one of amorphous silicon (a-Si), silicon nitride (SiNx), and silicon oxide (SiOx) or a multiple layer thereof, but is not limited thereto. However, the lower buffer layer 111 is not an essential configuration and may be omitted depending on a type of a transistor disposed on the substrate 110.

The first transistor T1 may be disposed on the substrate 110.

The first transistor T1 may include a first active layer A1, a first gate electrode G1, a first source electrode S1, and a first drain electrode D1. However, depending on the design of the pixel circuit, the source electrode may serve as a drain electrode and the drain electrode may serve as a source electrode.

The first active layer A1 may be disposed on the lower buffer layer 111. The first active layer A1 is an area in which a channel is formed when the first transistor T1 is driven. The first active layer A1 may include low temperature polycrystalline silicon (LTPS), such as amorphous silicon or polycrystalline silicon, exemplary embodiments of the present disclosure are not limited thereto.

The first active layer A1 may include a source region and a drain region including a p-type or n-type impurity, and a channel between the source region and the drain region and may further include a lightly doped region between the source region and the drain region which are adjacent to the channel.

The source region and the drain region are areas in which the impurity is highly doped and are connected to a first source electrode S1 and a first drain electrode D1 of the first transistor T1, respectively. As an impurity ion, a p-type impurity or an n-type impurity is used. For example, the p-type impurity may be one of boron (B), aluminum (Al), gallium (Ga), and indium (In) and for example, the n-type impurity may be one of phosphorus (P), arsenic (As), and antimony (Sb).

In the first active layer A1, the channel region may be doped with the n-type impurity or the p-type impurity depending on an NMOS or PMOS transistor structure and the NMOS or PMOS transistor may be applied.

The first gate insulating layer 112a may be disposed on the first active layer A1. The first gate insulating layer 112a may be configured by a single layer of silicon nitride (SiNx) or silicon oxide (SiOx) or a multi-layer thereof. In the first gate insulating layer 112a, a contact hole through which the first source electrode S1 and the first drain electrode D1 of the first transistor T1 are connected to the source region and the drain region of the first active layer A1 of the first transistor T1, respectively, may be formed.

The first gate electrode G1 of the first transistor T1 may be disposed on the first gate insulating layer 112a. For example, the first gate electrode G1 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The first gate electrode G1 may be formed on the first gate insulating layer 112a so as to overlap the channel region of the first active layer A1 of the first transistor T1.

A first capacitor electrode C1 of the storage capacitor Cst may be disposed on the first gate insulating layer 112a. For example, the first capacitor electrode C1 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The first capacitor electrode C1 may be omitted based on a driving characteristic of the display device 100 and a structure and a type of the transistor.

The first gate electrode G1 and the first capacitor electrode C1 may be formed by the same process. Further, the first gate electrode G1 and the first capacitor electrode C1 may be formed of the same material on the same layer, but the exemplary embodiments of the present disclosure are not limited thereto.

The first interlayer insulating layer 113a may be disposed on the first gate insulating layer 112a and the first gate electrode G1. In the first interlayer insulating layer 113a, a contact hole for exposing the first source region and the first drain region of the first active layer A1 of the first transistor T1 may be formed. For example, the first interlayer insulating layer 113a may be configured by a single layer of silicon nitride (SiNx) or silicon oxide (SiOx) or a multi-layer thereof, but the exemplary embodiments of the present disclosure are not limited thereto.

A second capacitor electrode C2 of the storage capacitor Cst may be disposed on the first interlayer insulating layer 113a. The second capacitor electrode C2 may be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

The second capacitor electrode C2 may be formed on the first interlayer insulating layer 113a so as to overlap the first capacitor electrode C1. Further, the second capacitor electrode C2 may be formed of the same material as the first capacitor electrode C1, but the exemplary embodiments of the present disclosure are not limited thereto. The second capacitor electrode C2 may be omitted based on a driving characteristic of the display device 100 and a structure and a type of the transistor, but is not limited thereto.

The upper buffer layer 114 may be disposed on the first interlayer insulating layer 113a. The upper buffer layer 114 are formed of a single layer or multiple layers, but the exemplary embodiments of the present disclosure are not limited thereto. For example, the upper buffer layer 114 may be formed by a single layer of any one of amorphous silicon (a-Si), silicon nitride (SiNx), and silicon oxide (SiOx) or a multiple layer thereof, but is not limited thereto.

The second transistor T2 may be disposed on the upper buffer layer 114.

The second transistor T2 may include a second active layer A2, a second gate electrode G2, a second source electrode S2, and a second drain electrode D2. However, depending on the design of the pixel circuit, the second source electrode S2 may serve as a drain electrode and the second drain electrode D2 may serve as a source electrode.

The second active layer A2 may be disposed on the upper buffer layer 114. The second active layer A2 may include an oxide semiconductor material formed of metal oxide, such as indium-gallium-zinc-oxide (IGZO), indium-zinc-oxide (IZO), indium-gallium-tin-oxide (IGTO), or indium-gallium-oxide (IGO), but the exemplary embodiments of the present disclosure are not limited thereto.

For example, the second active layer A2 may be formed of an oxide semiconductor. The oxide semiconductor material has a larger band gap than a silicon material so that electrons may not jump over the band gap in an off state. Therefore, the oxide semiconductor material has a low off-current. Therefore, the transistor including an active layer which is formed of an oxide semiconductor is suitable for a switching transistor which maintains a short on-time and a long off-time, but is not limited thereto.

For example, the second active layer A2 may include a source region and a drain region including a p-type or n-type impurity, and a channel between the source region and the drain region and may further include a lightly doped region between the source region and the drain region which are adjacent to the channel. The source region is a part of the second active layer A2 which is connected to the second source electrode S2 and the drain region may be a part of the second active layer A2 which is connected to the second drain electrode D2. For example, the source region and the drain region may be configured by ion-doping (impurity doping) of the second active layer A2. The source region and the drain region may be generated by doping ions into the oxide semiconductor material and the channel region may be a part in which the ions are not doped, but the oxide semiconductor material remains.

The second gate insulating layer 112b may be disposed on the second active layer A2. The second gate insulating layer 112b may be configured by a single layer of silicon nitride (SiNx) or silicon oxide (SiOx) or a multi-layer thereof, but the exemplary embodiments of the present disclosure are not limited thereto. In the second gate insulating layer 112b, a contact hole through which the second source electrode S2 and the second drain electrode D2 of the second transistor T2 are connected to the source region and the drain region of the second active layer A2 of the second transistor T2, respectively, may be formed. The second gate insulating layer 112b may be a gate insulating layer, but the exemplary embodiments of the present disclosure are not limited thereto.

The second gate electrode G2 of the second transistor T2 may be disposed on the second gate insulating layer 112b.

For example, the second gate electrode G2 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The second gate electrode G2 may be formed on the second gate insulating layer 112b so as to overlap the channel region of the second active layer A2 of the second transistor T2.

The second interlayer insulating layer 113b may be disposed on the second gate insulating layer 112b and the second gate electrode G2. The second interlayer insulating layer 113b may be configured by a single layer of silicon nitride (SiNx) or silicon oxide (SiOx) or a multi-layer thereof, but the exemplary embodiments of the present disclosure are not limited thereto.

The first source electrode S1, the first drain electrode D1, the second source electrode S2, and the second drain electrode D2 may be disposed on the second interlayer insulating layer 113b.

The first source electrode S1 and the first drain electrode D1 may be electrically connected to the first active layer A1 of the first transistor T1 through contact holes of the first gate insulating layer 112a, the first interlayer insulating layer 113a, the upper buffer layer 114, the second gate insulating layer 112b, and the second interlayer insulating layer 113b.

The second source electrode S2 and the second drain electrode D2 may be electrically connected to the second active layer A2 of the second transistor T2 through contact holes of the second gate insulating layer 112b and the second interlayer insulating layer 113b.

The first source electrode S1, the first drain electrode D1, the second source electrode S2, and the second drain electrode D2 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but are not limited thereto.

The first insulating layer 115 may be disposed on the first source electrode S1, the first drain electrode D1, the second source electrode S2, the second drain electrode D2, and the second interlayer insulating layer 113b.

The first insulating layer 115 may be an organic layer which planarizes and protects upper portions of the first transistor T1 and the second transistor T2. Therefore, the first insulating layer 115 may also be referred to as a first planarization layer. For example, the first insulating layer 115 may be formed of an organic material such as acryl resin, epoxy resin, phenolic resin, polyamide resin, or polyimide resin, but the exemplary embodiments of the present disclosure are not limited thereto.

A first connection electrode AE1 and a second connection electrode AE2 may be disposed on the first insulating layer 115.

The first connection electrode AE1 may be connected to the first drain electrode D1 of the first transistor T1 through the contact hole of the first insulating layer 115. Therefore, the first connection electrode AE1 may be configured to electrically connect the first transistor T1 and the light emitting diode 120.

The second connection electrode AE2 may be connected to the second drain electrode D2 of the second transistor T2 and the first capacitor electrode C1 of the storage capacitor Cst through the contact hole of the first insulating layer 115.

The first connection electrode AE1 and the second connection electrode AE2 may be formed of a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof, but are not limited thereto.

A second insulating layer 116 may be disposed on the first insulating layer 115, the first connection electrode AE1, and the second connection electrode AE2. A top surface of the second insulating layer 116 may have a surface parallel to the substrate 110. Therefore, the second insulating layer 116 may planarize a step which may be caused by the components disposed therebelow. Therefore, the second insulating layer 116 may also be referred to as a second planarization layer. For example, the second insulating layer 116 may be formed of one or more materials of acrylic-based resin, epoxy resin, phenolic resin, polyamides resin, polyimides resin, unsaturated polyesters resin, polyphenylene resin, polyphenylenesulfides resin, and benzocyclobutene, but is not limited thereto.

The light emitting diode 120 may be disposed on the second insulating layer 116.

The light emitting diode 120 may include an anode 121, an emission layer 122, and a cathode 123.

The anode 121 may be disposed on the second insulating layer 116. The anode 121 may be connected to the first connection electrode AE1 through a contact hole of the second insulating layer 116 and may be electrically connected to the first transistor T1. The anode 121 may be formed of a metallic material, but the exemplary embodiments of the present disclosure are not limited thereto.

When the display device 100 is a top emission type in which light emitted from the light emitting diode 120 is emitted above the substrate 110 on which the light emitting diode 120 is disposed, the anode 121 may include a reflective layer and a transparent conductive layer disposed on the reflective layer. For example, the transparent conductive layer may be formed of a transparent conductive oxide, such as indium tin oxide (ITO) and indium zinc oxide (IZO), but the exemplary embodiments of the present disclosure are not limited thereto. For example, the reflective layer may be formed of silver (Ag), aluminum (Al), gold (Au), molybdenum (Mo), tungsten (W), chrome (Cr), or an alloy thereof, but is not limited thereto.

The bank layer 117 may be disposed on the anode 121. The bank layer 117 may be disposed while covering an end of the anode 121. A part of the bank layer 117 corresponding to an emission area of the sub pixel SP may be open. A part of the anode 121 may be exposed through the open part of the bank layer 117 (hereinafter, referred to as an open area). The bank layer 117 may be formed of an inorganic insulating material, such as silicon nitride (SiNx) or silicon oxide (SiOx), or an organic insulating material, such as benzocyclobutene-based resin, acrylic-based resin or imide-based resin, but is not limited thereto. The bank layer 117 may be formed of a material including a black pigment or an organic material, such as polyimide resin or a photo sensitive polymer, but the exemplary embodiments of the present disclosure are not limited thereto. When the bank layer 117 is configured with a material including a black pigment or a black dye, the bank may be a black bank. When the bank layer 117 is configured with a material including a black pigment or a black dye, light from the outside is blocked or light reflected from the outside is blocked so that a luminance of the display device may further be improved. A spacer 117a may be further disposed on the bank layer 117. The spacer 117a may be configured with the same material as the bank layer 117, but the exemplary embodiments of the present disclosure are not limited thereto.

The emission layer 122 may be disposed on the anode 121. The emission layer 122 may be disposed in the open area of the bank layer 117 and in the vicinity of the open area. Therefore, the emission layer 122 may be disposed on the anode 121 exposed through the open area of the bank layer 117.

The emission layer 122 may include a plurality of organic material layers. For example, the emission layer 122 may include an organic layer, such as a hole injection layer, a hole transport layer, an electron transport layer, and an electron injection layer, but the exemplary embodiments of the present disclosure are not limited thereto. When the emission layer 122 emits white light, light emitted from the emission layer 122 may be converted into light with various colors by a plurality of color filters, but is not limited thereto.

The cathode 123 may be disposed on the emission layer 122. The cathode 123 supplies electrons to the emission layer 122 so that the cathode may be formed of a conductive material having a low work function. The cathode 123 may be formed as one layer over the plurality of sub pixels SP. For example, the cathodes 123 of the plurality of sub pixels SP are connected to each other to be integrally formed.

For example, the cathode 123 may be formed of a transparent conductive material such as indium tin oxide (ITO) and indium zinc oxide (IZO) or ytterbium (Yb) alloy and may further include a metal doping layer, but is not limited thereto.

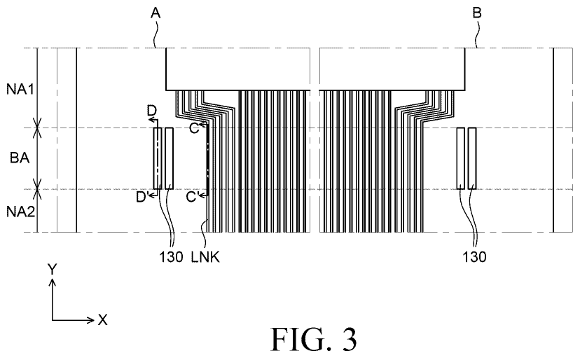

FIG. 3 is a plan view of enlarging areas A and B of FIG. 1.

Referring to FIG. 3, the display device 100 according to the exemplary embodiment of the present disclosure includes a plurality of first holes 130 disposed along a bending direction in the bending area BA.

A link line LNK may be disposed in a center portion of the bending area BA and the plurality of first holes 130 may be disposed in both side portions of the bending area BA. The plurality of first holes 130 may be disposed in a remaining area of the bending area BA in which the link line LNK is not disposed. For example, the plurality of first holes 130 may be disposed in both sides of the link line LNK.

The plurality of first holes 130 may be disposed on one side and the other side of the bending area BA. The plurality of first holes 130 may be disposed to be adjacent to each other. The plurality of first holes 130 may be disposed to be spaced apart from each other in a direction intersecting the bending direction to be parallel. The plurality of first holes 130 may be disposed such that a major axis is parallel to the bending direction. For example, the plurality of first holes 130 extends in the Y-axis direction and may be disposed to be spaced apart from each other in the X-axis direction to be parallel to each other. However, the exemplary embodiment of the present disclosure is not limited thereto and the plurality of first holes 130 may be disposed on one side and the other side of the bending area BA.

A planar shape of the plurality of first holes 130 may be a quadrangular shape, such as a rectangle or a square. When the plurality of first holes 130 has a circular shape, stress is irregularly concentrated in every position with respect to the bending direction so that it is highly likely to cause a crack. In contrast, when the plurality of first holes 130 has a quadrangular shape, the stress is applied in a direction parallel to the bending direction to suppress the concentration of the stress in every position to minimize the generation of the crack.

The plurality of first holes 130 may be configured to have the same length. For example, the length of the plurality of first holes 130 may correspond to the bending area BA. For example, a length of the plurality of first holes 130 in the Y-axis direction is equal to a length of the bending area in the Y-axis direction and both ends of the plurality of first holes 130 may be disposed at the boundary of the bending area BA.

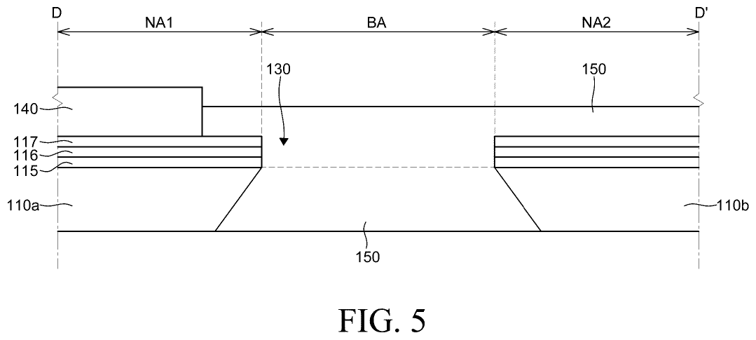

FIG. 4 is a cross-sectional view taken along C-C′ of FIG. 3. FIG. 5 is a cross-sectional view taken along D-D′ of FIG. 3. In FIGS. 4 and 5, for the convenience of illustration, among various components of the display device 100, only a first substrate 110a, a second substrate 110b, a first insulating layer 115, a link line LNK, a second insulating layer 116, a bank layer 117, a first hole 130, a polarizer 140, and a micro coating layer 150 are schematically illustrated.

Referring to FIGS. 4 and 5, the substrate 110 includes a first substrate 110a and a second substrate 110b which is spaced apart from the first substrate 110a. In the meantime, in FIGS. 4 and 5, it is illustrated that the first substrate 110a and the second substrate 110b are spaced apart from each other with the bending area BA therebetween, but the first substrate 110a and the second substrate 110b may be at least partially connected.

In the meantime, when a mother glass board is etched, a hole and a cell are separated to form the first substrate 110a and the second substrate 110b of the substrate 110. That is, the mother glass substrate of the bending area BA is selectively removed to be simultaneously formed to form a structure in which a bezel is bendable. For example, a process of forming the bending area BA on the substrate 110 will be explained. A mask is formed on a rear surface of a mother glass board and a part of the mask is removed to form a hole. At this time, a process of forming a hole is referred to as a process of removing a mask from the mother glass board by cutting the mask with laser and separating a hole and a cell from the mother glass board. Next, after primarily etching a part of the mother glass board through a mask in accordance with a portion in which the bending area BA is to be formed, the mask is removed and the entire rear surface of the mother glass board may be etched. Further, after reducing a thickness of the rear surface of the mother glass board, a primarily etched part is completely removed to form the bending area BA.

The first substrate 110a may be disposed in an active area AA and a first non-active area NA1 enclosing the active area AA.

A side surface of the first substrate 110a which is adjacent to the bending area BA may be an inclined surface. An end of a top surface of the first substrate 110a may be disposed to be adjacent to the bending area BA more than an end of a bottom surface. Therefore, a side surface of the first substrate 110a which is adjacent to the bending area BA may be an inclined surface. Therefore, an inclination angle of the side surface of the first substrate 110a which is adjacent to the bending area BA may be 45 degrees, but is not limited thereto. The side surface of the first substrate 110a which is adjacent to the bending area BA may be formed as a concave surface.

The second substrate 110b may be disposed in the second non-active area NA2. That is, the second substrate 110b may be disposed in the second non-active area NA2 extending from the bending area BA. Therefore, one end of the second substrate 110b may be in contact with the bending area BA.

A side surface of the second substrate 110b which is adjacent to the bending area BA may be an inclined surface. An end of a top surface of the second substrate 110b may be disposed to be adjacent to the bending area BA more than an end of a bottom surface. Therefore, a side surface of the second substrate 110b which is adjacent to the bending area BA may be an inclined surface. Therefore, an inclination angle of the side surface of the second substrate 110b which is adjacent to the bending area BA may be 45 degrees, but is not limited thereto. The side surface of the second substrate 110b which is adjacent to the bending area BA may be formed as a concave surface.

The first insulating layer 115 is disposed on the first substrate 110a and the second substrate 110b. The first insulating layer extends on the first substrate and the second substrate to be disposed in the bending area BA. At this time, a bottom surface of the first insulating layer 115 may be exposed from the first substrate 110a and the second substrate 110b in the bending area BA. Specifically, the first insulating layer 115 may be a configuration for suppressing a damage of a configuration disposed above the first substrate 110a and the second substrate 110b due to the etching when an etching process required to form the first substrate 110a and the second substrate 110b is performed. Therefore, the first insulating layer 115 may be referred to as an etch stop layer.

The first insulating layer 115 may be configured by an organic material and specifically, configured by a material resistant to a glass etchant and a material having a corrosion resistance. For example, as the etchant for glass etching, an etchant including nitric acid (HNO3) or hydrofluoric acid (HF) may be used. The first insulating layer 115 may include any one of silicon based organic material, urethane, polyimide, and photo acryl.

Accordingly, the display device according to the exemplary embodiment of the present disclosure includes the first insulating layer 115 disposed between the first substrate 110a and the second substrate 110b and the link line LNK in the bending area BA. Therefore, the damage of the components disposed on the first substrate 110a and the second substrate 110b due to the glass etching process which form side surfaces of the first substrate 110a and the second substrate 110b may be suppressed.

The link line LNK may be disposed on the first insulating layer 115 across the bending area BA. The link line LNK may be disposed on the same layer as the first connection electrode AE1 and the second connection electrode AE2. The link line LNK is formed of a conductive material and may be formed of a conductive material having an excellent ductility to reduce the crack generated at the time of bending the substrate 110. For example, the link line LNK may be formed of a conductive material having excellent ductility such as gold (Au), silver (Ag), and aluminum (Al) and formed of one of various conductive materials used in the active area AA. The link line LNK may also be configured by molybdenum (Mo), chrome (Cr), titanium (Ti), nickel (Ni), neodymium (Nd), copper (Cu), and an alloy of silver (Ag), and magnesium (Mg). Further, the link line LNK may be configured by a multi-layered structure including various conductive materials and for example, configured by a triple layered structure of titanium (Ti)/aluminum (Al)/titanium (Ti), but the structure of the link line LNK according to the present disclosure is not limited thereto. In the meantime, when the first connection electrode AE1 and the second connection electrode AE2 are not disposed and the first drain electrode D1 is directly connected to the anode 121, the link line LNK may be disposed on the same layer as the first drain electrode D1 or the first source electrode S1.

The second insulating layer 116 extends from the first substrate 110a and the second substrate 110b to be disposed in the bending area BA. The second insulating layer 116 may be disposed on the link line LNK.

The bank layer 117 extends from the first substrate 110a and the second substrate 110b to be disposed in the bending area BA. The bank layer 117 may be disposed on the second insulating layer 116. The bank layer 117 may be omitted depending on the design.

The first hole 130 may be disposed in at least a part of the plurality of insulating layers 115, 116, and 117. Specifically, the first hole 130 may be disposed in the first insulating layer 115, the second insulating layer 116, and the bank layer 117.

A polarizer 140 may be disposed in the first non-active area NA1. The polarizer 140 may be disposed on the first substrate 110a. The polarizer 140 is disposed on the first substrate 110a and may be in contact with the micro coating layer 150 in the first non-active area NA1.

The micro coating layer 150 is disposed so as to overlap at least a part of the first non-active area NA1 and the second non-active area NA2 and may be disposed on the link line LNK in the bending area BA. Specifically, the micro coating layer 150 may be disposed on the bank layer 117. The micro coating layer 150 extends from the first non-active area NA1 to be in contact with the polarizer 140 to be disposed in the bending area BA and at least a part of the second non-active area NA2.

Since a tensile force is applied to the link line LNK disposed on the first insulating layer 115 while being bent to cause minute crack, the micro coating layer 150 may be formed by coating a position to be bent with a resin with a small thickness to protect the link line LNK. At this time, the micro coating layer is configured by resin and for example, may be configured by an acrylic-based material or urethane acrylate, but is not limited thereto.

The micro coating layer 150 may adjust a neutral plane of the bending area BA. The neutral plane means a virtual plane that is not stressed because the compressive force and the tensile force applied to the structure are canceled each other when the structure is bent. When two or more structures are laminated, a virtual neutral plane may be formed between structures. When the entire structure is bent in one direction, structures disposed in the bending direction with respect to the neutral plane are compressed by the bending so that a compressive force is applied thereto. In contrast, the structures which are disposed in an opposite direction to the bending direction with respect to the neutral plane are stretched due to the bending so that a tensile force is applied thereto. Further, normally, when the structures are applied with the tensile force between the compressive force and the tensile force, the structures are more susceptible, so that when the tensile force is applied, the structures are more likely to be cracked.

The first insulating layer 115 disposed below the neutral plane is compressed to be applied with the compressive force and the link line LNK disposed on the upper portion is applied with the tensile force so that the cracks may be generated due to the tensile force. Accordingly, in order to minimize the tensile force applied to the link line LNK, the micro coating layer 150 may be located on the neutral plane.

Therefore, the micro coating layer 150 is disposed on the bending area BA to raise the neutral plane to the upward direction and the neutral plane is formed in the same position as the wiring line or the wiring line is disposed to be higher than the neutral plane. Therefore, the stress is not applied or the compressive force is applied while being bent, so that generation of a crack may be suppressed.

The micro coating layer 150 may be disposed below the first insulating layer 115 in the bending area BA, wherein the first insulating layer 115 may be single layer or plurality of layers. Specifically, the micro coating layer 150 may also be disposed below the first insulating layer 115. That is, the micro coating layer 150 may be disposed in the bending area BA between the first substrate 110a and the second substrate 110b below the first insulating layer. Therefore, the micro coating layer 150 is also disposed not only above the first insulating layer 115, but also below the first insulating layer 115, in the bending area BA so that the stress is not applied or the compressive force is applied while being bent, which suppresses the generation of a crack.

The micro coating layer 150 may be disposed so as to be filled in the plurality of first holes 130. Specifically, the plurality of first holes 130 is filled with the micro coating layer 150 and the micro coating layer 150 may be disposed in an upper area and a lower area of the plurality of first holes 130.

In the display device of the related art, during the manufacturing process, when a lamination process is performed or the bending area is bent, the stress is concentrated on an edge of the bending area to cause the crack and the generated crack propagates to a center direction of the bending area to cause a damage of the display device or degrade the reliability.

Therefore, in the display device 100 according to the exemplary embodiment of the present disclosure, the generation of the crack may be minimized. Specifically, the display device 100 according to the exemplary embodiment of the present disclosure includes a plurality of first holes 130 disposed along a bending direction in the bending area BA. A planar surface shape of the plurality of first holes 130 is a quadrangular shape and the plurality of first holes 130 is disposed in the first insulating layer 115, the second insulating layer 116, and the bank layer 117 and the micro coating layer 150 is filled in the plurality of first holes 130. Accordingly, in the display device 100 according to the exemplary embodiment of the present disclosure, the plurality of first holes 130 is disposed along the bending direction in the bending area BA. Therefore, concentration of the stress in the bending area BA while being bent is reduced to minimize cracks generated in the bending area BA and improve the reliability of the display device 100.

In the display device 100 according to the exemplary embodiment of the present disclosure, the generation and propagation of the crack during bending may be suppressed.

Specifically, in the display device 100 according to the exemplary embodiment of the present disclosure, the plurality of first holes 130 are disposed in both sides of the link line LNK disposed in the center portion of the bending area BA. Further, the plurality of first holes 130 is disposed in the first insulating layer 115, the second insulating layer 116, and the bank layer 117 and the micro coating layer 150 is filled in the plurality of first holes 130. Accordingly, in the display device 100 according to the exemplary embodiment of the present disclosure, even though a crack is generated from the edge of the bending area BA, propagation of the crack to the center portion of the bending area BA through the first insulating layer 115, the second insulating layer 116, and the bank layer 117 may be suppressed.

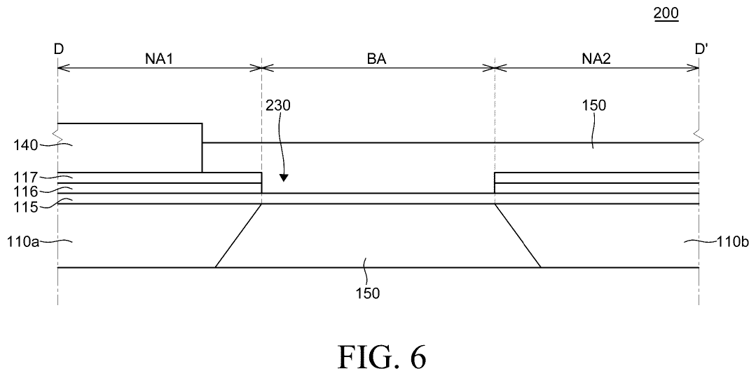

FIG. 6 is a cross-sectional view of a non-active area of a display device according to another exemplary embodiment of the present disclosure. FIG. 6 is a cross-sectional view of the same area as FIG. 5. FIG. 6 has the substantially same configuration as the display device 100 of FIG. 5 except for a first hole 230 so that a redundant description is omitted.

Referring to FIG. 6, a display device 200 according to another exemplary embodiment of the present disclosure includes a plurality of first holes 230 in at least a part of a plurality of insulating layers 115, 116, and 117.

Specifically, the plurality of first holes 230 may be disposed in the second insulating layer 116 and the bank layer 117. For example, the plurality of first holes 230 may be disposed in the second insulating layer 116 and the bank layer 117 so as to expose a part of a top surface of the first insulating layer 115.

The micro coating layer 150 may be disposed so as to be filled in the plurality of first holes 230. For example, the plurality of first holes 230 is filled with the micro coating layer 150 and the micro coating layer 150 may also be disposed in an upper area of the plurality of first holes 230.

Therefore, in the display device 200 according to another exemplary embodiment of the present disclosure, the plurality of first holes 230 is disposed along the bending direction in the bending area BA and has a quadrangular shape, and the micro coating layer 150 is filled in the plurality of first holes 230. Accordingly, in the display device 200 according to another exemplary embodiment of the present disclosure, the concentration of the stress in the bending area BA while being bent is reduced to minimize a crack from being generated in the bending area BA and improve the reliability of the display device 200.

In the display device 200 according to another exemplary embodiment of the present disclosure, the plurality of first holes 230 is disposed in the bending direction between the edge of the bending area BA and the link line of the center portion of the bending area BA. The micro coating layer 150 is disposed so as to be filled in the plurality of first holes 230. Accordingly, in the display device 200 according to another exemplary embodiment of the present disclosure, even though a crack is generated from the edge of the bending area BA, the crack may be suppressed from propagating to the center portion of the bending area BA through the insulating layer.

In the display device 200 according to another exemplary embodiment of the present disclosure, the plurality of first holes 230 is disposed in the second insulating layer 116 and the bank layer 117. Accordingly, in the display device 200 according to another exemplary embodiment of the present disclosure, when the plurality of first holes 230 is formed, the plurality of first holes 230 is disposed only in the second insulating layer 116 and the bank layer 117 excluding the first insulating layer 115. Accordingly, in the display device 200 according to another exemplary embodiment of the present disclosure, when performing an etching process for forming the plurality of first holes 230 in the bending area in which the substrate 110 is not disposed, the damage caused by the etching is minimized to suppress the damage and improve the reliability.

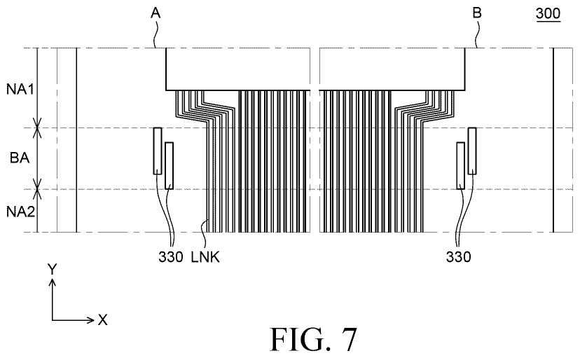

FIG. 7 is an enlarged plan view of a display device according to still another exemplary embodiment of the present disclosure. FIG. 7 is an enlarged plan view for the same area as FIG. 3. FIG. 7 has the substantially same configuration as the display device 100 of FIG. 3 except for a first hole 330 so that a redundant description is omitted.

Referring to FIG. 7, the display device 300 according to still another exemplary embodiment of the present disclosure includes a plurality of first holes 330 which is disposed to be staggered along a bending direction in the bending area BA.

A link line LNK may be disposed in a center portion of the bending area BA and the plurality of first holes 330 may be disposed in both side portions of the bending area BA. The plurality of first holes 330 may be disposed in a remaining area of the bending area BA in which the link line LNK is not disposed. For example, the plurality of first holes 330 may be disposed in both sides of the link line LNK.

The plurality of first holes 330 may be disposed to be adjacent to each other. The plurality of first holes 330 may be disposed to be spaced apart from each other in a direction intersecting the bending direction to be parallel. The plurality of first holes 330 may be disposed such that a major axis is parallel to the bending direction. For example, the plurality of first holes 330 extends in the Y-axis direction and may be disposed to be spaced apart from each other in the X-axis direction to be parallel to each other.

The plurality of first holes 330 may be configured to have the same length. A length of the plurality of first holes 330 in the Y-axis direction is smaller than a length of the bending area BA in the Y-axis direction. The plurality of first holes 330 may be disposed to be staggered. For example, among the plurality of first holes 330, a center of one first hole 330 and a center of another first hole 330 may be disposed to be staggered. For example, an end of at least one first hole 330, among the plurality of first holes 330, is disposed in the bending area BA and the boundary of the bending area BA and the other end may be disposed to be spaced apart from the boundary of the bending area BA with a predetermined interval. Further, an end of at least the other one first hole 330, among the plurality of first holes 330, is disposed to be spaced apart with a predetermined interval in the bending area BA and the boundary of the bending area BA and the other end may be disposed in the boundary of the bending area BA.

Therefore, in the display device 300 according to still another exemplary embodiment of the present disclosure, a plurality of first holes 330 is disposed along a bending direction in the bending area BA. The plurality of first holes 330 is spaced apart from each other and may be disposed to be staggered. The plurality of first holes 330 has a quadrangular shape and the micro coating layer 150 is filled in the plurality of first holes 330. Accordingly, in the display device 300 according to still another exemplary embodiment of the present disclosure, the concentration of the stress in the bending area BA while being bent is reduced to minimize a crack from being generated in the bending area BA and improve the reliability of the display device 300.

In the display device 300 according to still another exemplary embodiment of the present disclosure, the plurality of first holes 330 is disposed in the bending direction between the edge of the bending area BA and the link line in the center portion of the bending area BA. The plurality of first holes 330 is disposed in the first insulating layer 115, the second insulating layer 116, and the bank layer 117 and the micro coating layer 150 is disposed so as to be filled in the plurality of first holes 330. Accordingly, in the display device 300 according to still another exemplary embodiment of the present disclosure, even though a crack is generated from the edge of the bending area BA, the crack may be suppressed from propagating to the center portion of the bending area BA through the insulating layer.

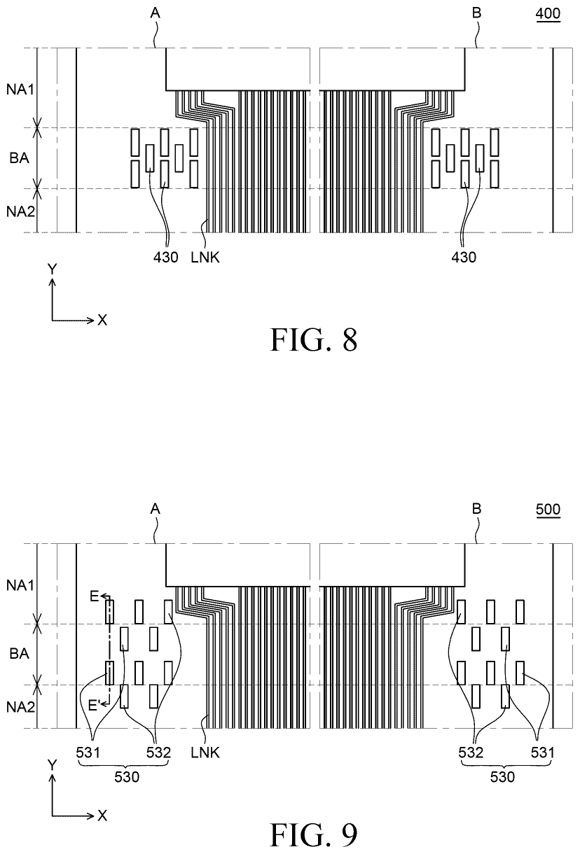

FIG. 8 is an enlarged plan view of a display device according to still another exemplary embodiment of the present disclosure. FIG. 8 is an enlarged plan view for the same area as FIG. 3. FIG. 8 has the substantially same configuration as the display device 100 of FIG. 3 except for a first hole 430 so that a redundant description is omitted.

Referring to FIG. 8, the display device 400 according to still another exemplary embodiment of the present disclosure includes a plurality of first holes 430 which is disposed to be staggered along a bending direction in the bending area BA.

A link line LNK may be disposed in a center portion of the bending area BA and the plurality of first holes 430 may be disposed in both side portions of the bending area BA. The plurality of first holes 430 may be disposed in a remaining area of the bending area BA in which the link line LNK is not disposed. For example, the plurality of first holes 430 may be disposed in both sides of the link line LNK.

The plurality of first holes 430 may be disposed to be adjacent to each other. The plurality of first holes 430 may be disposed to be spaced apart from each other in a direction intersecting the bending direction to be parallel and may be disposed to be spaced apart from each other along the bending direction. The plurality of first holes 430 may be disposed such that a major axis is parallel to the bending direction. For example, the plurality of first holes 430 extends in the Y-axis direction and is disposed to be spaced apart from each other in the Y-axis direction and may be disposed to be spaced apart in the X-axis direction to be parallel to each other.

Among the plurality of first holes 430, a plurality of first holes 430 which is spaced apart from each other in a direction intersecting the bending direction may be disposed to be staggered. For example, among the plurality of first holes 430, an end of one first hole 430 may be disposed so as to correspond to a center of first holes 430 which are spaced apart in the X-axis direction. For example, referring to FIG. 8, two first holes 430 disposed on the same line in the Y-axis direction and one first hole 430 spaced apart therefrom in the X-axis direction may be disposed to be staggered in the X-axis direction.

The plurality of first holes 430 may be configured to have the same length. However, the present disclosure is not limited thereto and the plurality of first holes may be configured to have different lengths.

Therefore, in the display device 400 according to still another exemplary embodiment of the present disclosure, a plurality of first holes 430 is disposed along a bending direction in the bending area BA. The plurality of first holes 430 is spaced apart from each other and is disposed to be staggered in the bending direction and in a direction perpendicular to the bending direction. The plurality of first holes 430 has a quadrangular shape and the micro coating layer 150 is filled in the plurality of first holes 430. Accordingly, in the display device 400 according to still another exemplary embodiment of the present disclosure, the concentration of the stress in the bending area BA while being bent is reduced to minimize a crack from being generated in the bending area BA and improve the reliability of the display device 400.

In the display device 400 according to still another exemplary embodiment of the present disclosure, the plurality of first holes 430 is disposed in the bending direction between the edge of the bending area BA and the link line in the center portion of the bending area BA. The plurality of first holes 430 is disposed in the first insulating layer 115, the second insulating layer 116, and the bank layer 117 and the micro coating layer 150 is disposed so as to be filled in the plurality of first holes 430. Accordingly, when the crack is generated from the edge of the bending area BA, the crack may be suppressed from propagating to the center portion of the bending area BA through the insulating layer.

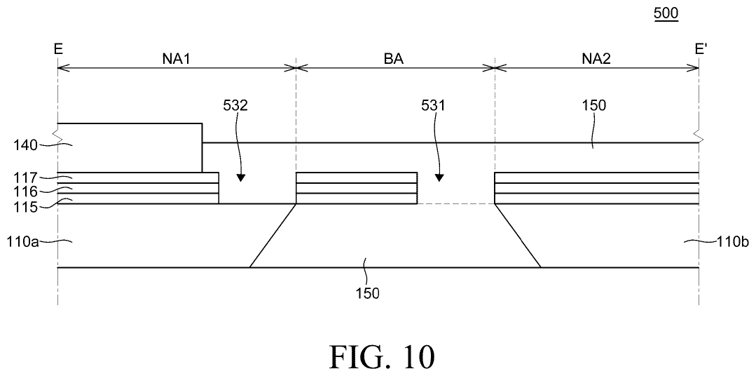

FIG. 9 is an enlarged plan view of a display device according to still another exemplary embodiment of the present disclosure. FIG. 10 is a cross-sectional view taken along E-E′ of FIG. 9. FIG. 9 is an enlarged plan view for the same area as FIG. 3. FIG. 9 has the substantially same configuration as the display device 100 of FIG. 3 except for a hole 530 so that a redundant description is omitted.

Referring to FIGS. 9 and 10, a display device 500 according to still another exemplary embodiment of the present disclosure includes holes 530 disposed in a bending area BA and a first non-active area NA1 and a second non-active area NA2 adjacent to the bending area BA. The holes 530 may include a plurality of first holes 531 and a plurality of second holes 532.

The plurality of first holes 531 may be disposed along the bending direction in the bending area BA and may be disposed to be staggered from each other.

A link line LNK may be disposed in a center portion of the bending area BA and the plurality of first holes 531 may be disposed in both side portions of the bending area BA. The plurality of first holes 531 may be disposed in a remaining area of the bending area BA in which the link line LNK is not disposed. For example, the plurality of first holes 531 may be disposed in both sides of the link line LNK, respectively.

The plurality of first holes 531 may be disposed to be adjacent to each other. The plurality of first holes 531 may be disposed to be spaced apart from each other in a direction intersecting the bending direction to be parallel. The plurality of first holes 531 may be disposed such that a major axis is parallel to the bending direction. For example, the plurality of first holes 531 extends in the Y-axis direction and may be disposed to be spaced apart from each other in the X-axis direction to be parallel to each other.

The plurality of first holes 531 may be disposed to be staggered from each other. For example, referring to FIG. 9, among the plurality of first holes 531, one end of one first hole 531 is disposed in a boundary with the second non-active area NA2 and the other one is disposed in a position corresponding to one end of the other adjacent first hole 531. The other end of the other first hole 531 may be disposed in a boundary with the first non-active area NA1.

The plurality of second holes 532 is disposed in the first non-active area NA1 and the second non-active area NA2 and may be disposed to be adjacent to the bending area BA.

The plurality of second holes 532 may be disposed on both edges of the first non-active area NA1 and the second non-active area NA2. The plurality of second holes 532 may be disposed in an area adjacent to the bending area BA. For example, the plurality of second holes 532 is disposed between the link line LNK disposed in the first non-active area NA1 and both edges of the first non-active area NA1 and is disposed between the link line LNK disposed in the second non-active area NA2 and both edges of the second non-active area NA2. For example, one ends of the plurality of second holes 532 disposed in the first non-active area NA1 and the second non-active area NA2 may be disposed in the boundaries with the bending area BA.

The plurality of second holes 532 may be disposed to be adjacent to each other. The plurality of second holes 532 may be disposed to be spaced apart from each other in a direction intersecting the bending direction to be parallel. The plurality of second holes 532 may be disposed such that a major axis is parallel to the bending direction. For example, the plurality of second holes 532 extends in the Y-axis direction and may be disposed to be spaced apart from each other in the X-axis direction to be parallel to each other.

The plurality of second holes 532 may be disposed to be staggered from the plurality of first holes 531. For example, referring to FIG. 9, the plurality of second holes 532 may be disposed to be staggered from the plurality of adjacent first holes 531, respectively.

The plurality of first holes 531 and the plurality of second holes 532 may be configured to have the same length. However, the present disclosure is not limited thereto and the plurality of first holes and the plurality of second holes may be configured to have different lengths.

Referring to FIG. 10, the plurality of first holes 531 and the plurality of second holes 532 may be disposed in at least a part of the plurality of insulating layers 115, 116, and 117. Specifically, the plurality of first holes 531 and the plurality of second holes 532 may be disposed in the first insulating layer 115, the second insulating layer 116, and the bank layer 117. For example, the plurality of first holes 531 may be disposed so as to expose a top surface of the micro coating layer 150 disposed below the first insulating layer 115 and the plurality of second holes 532 may be disposed so as to expose a top surface of the first substrate 110a disposed below the first insulating layer 115.

The micro coating layer 150 may be disposed so as to be filled in the plurality of first holes 531 and the plurality of second holes 532. Specifically, the plurality of first holes 531 and the plurality of second holes 532 are filled with the micro coating layer 150 and the micro coating layer 150 may be disposed in an upper area of the plurality of first holes 531 and the plurality of second holes 532 and a lower area of the plurality of first holes 531.

Therefore, in the display device 500 according to still another exemplary embodiment of the present disclosure, the plurality of first holes 531 is disposed along the bending direction in the bending area BA and the plurality of second holes 532 is disposed along the bending direction in the first and second non-active areas NA1 and NA2 adjacent to the bending area BA. The plurality of first holes 531 and the plurality of second holes 532 are spaced apart from each other and are disposed to be staggered in the bending direction and in a direction perpendicular to the bending direction. The plurality of first holes 531 and the plurality of second holes 532 have a quadrangular shape and are filled with the micro coating layer 150. Accordingly, in the display device 500 according to still another exemplary embodiment of the present disclosure, the concentration of the stress in the bending area BA and the non-active areas NA1 and NA2 adjacent to the bending area BA while being bent is reduced. Therefore, a crack which is generated in the bending area BA and the non-active areas NA1 and NA2 is reduced and the reliability of the display device 500 may be improved.

In the display device 500 according to still another exemplary embodiment of the present disclosure, the plurality of first holes 531 is disposed in the bending direction between the edge of the bending area BA and the link line LNK in the center portion of the bending area BA. Further, the plurality of second holes 532 is disposed in the bending direction between the edges of each of the first non-active area NA1 and the second non-active area NA2 and the link line LNK in the center portion. The plurality of first holes 531 and the plurality of second holes 532 are disposed in the first insulating layer 115, the second insulating layer 116, and the bank layer 117 and are disposed so as to be filled with the micro coating layer 150. Accordingly, when the crack is generated from the edge of the bending area BA and the non-active areas NA1 and NA2, the crack may be suppressed from propagating to the center portions of the bending area BA and the non-actives area NA1 and NA2 through the insulating layer.

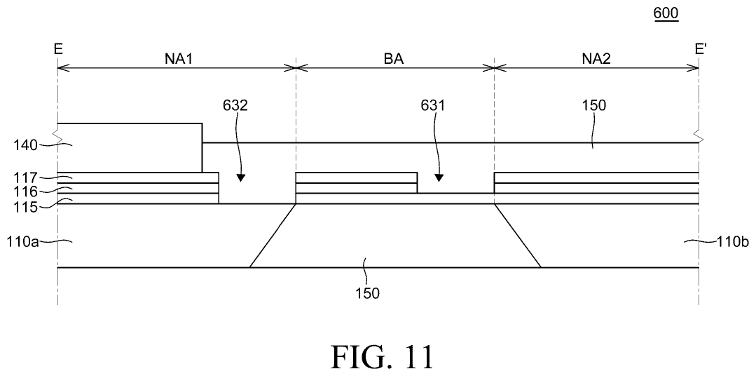

FIG. 11 is a cross-sectional view of a display device according to still another exemplary embodiment of the present disclosure. FIG. 11 is a cross-sectional view for the same position as FIG. 10. FIG. 11 has the substantially same configuration as the display device 500 of FIG. 10 except for a first hole 631 and a second hole 632 so that a redundant description is omitted.

A display device 600 according to still another exemplary embodiment of the present disclosure includes a plurality of first holes 631 disposed along a bending direction in a bending area BA and a plurality of second holes 632 disposed along the bending area in a first non-active area NA1 and a second non-active area NA2.

The plurality of first holes 631 may be disposed in the bending area BA. For example, referring to FIG. 11, one end of one of the plurality of first holes 631 may be disposed in a boundary with the second non-active area NA2.

The plurality of second holes 632 is disposed in the first non-active area NA1 and the second non-active area NA2. For example, referring to FIG. 11, the plurality of second holes 632 may be disposed in the first non-active area NA1 and one end may be disposed in a boundary with the bending area BA.

The plurality of first holes 631 and the plurality of second holes 632 may be disposed in at least a part of the plurality of insulating layers 115, 116, and 117.

Specifically, the plurality of second holes 632 is disposed in the first insulating layer 115, the second insulating layer 116, and the bank layer 117 and the plurality of first holes 631 may be disposed in the second insulating layer 116 and the bank layer 117. For example, referring to FIG. 11, the plurality of first holes 631 may be disposed so as to expose a top surface of the first insulating layer 115 and the plurality of second holes 632 may be disposed so as to expose a top surface of the first substrate 110a disposed below the first insulating layer 115.

The micro coating layer 150 may be disposed so as to be filled in the plurality of first holes 631 and the plurality of second holes 632. Specifically, the plurality of first holes 631 and the plurality of second holes 632 are filled with the micro coating layer 150 and the micro coating layer 150 may also be disposed in an upper area of the plurality of first holes 631 and the plurality of second holes 632.

Therefore, in the display device 600 according to still another exemplary embodiment of the present disclosure, the plurality of first holes 631 is disposed along the bending direction in the bending area BA and the plurality of second holes 632 is disposed along the bending direction in the first and second non-active areas NA1 and NA2 adjacent to the bending area BA. The plurality of first holes 631 and the plurality of second holes 632 are spaced apart from each other and are disposed to be staggered in the bending direction and in a direction perpendicular to the bending direction. The plurality of first holes 631 and the plurality of second holes 632 have a quadrangular shape and are filled with the micro coating layer 150. Accordingly, in the display device 600 according to still another exemplary embodiment of the present disclosure, the concentration of the stress in the bending area BA and the non-active areas NA1 and NA2 adjacent to the bending area BA while being bent is reduced. Therefore, a crack which is generated in the bending area BA and the non-active areas NA1 and NA2 is reduced and the reliability of the display device 600 may be improved.

In the display device 600 according to still another exemplary embodiment of the present disclosure, the plurality of first holes 631 is disposed in the bending direction between the edge of the bending area BA and the link line LNK in the center portion of the bending area BA. Further, the plurality of second holes 632 is disposed in the bending direction between the edges of each of the first non-active area NA1 and the second non-active area NA2 and the link line LNK in the center portion. The plurality of first holes 631 is disposed in the second insulating layer 116 and the bank layer 117 and the plurality of second holes 632 is disposed in the first insulating layer 115, the second insulating layer 116, and the bank layer 117 and the plurality of first holes 631 and the plurality of second holes 632 are disposed to be filled with the micro coating layer 150. Accordingly, when the crack is generated from the edge of the bending area BA and the non-active areas NA1 and NA2, the crack may be suppressed from propagating to the center portions of the bending area BA and the non-actives area NA1 and NA2 through the insulating layer.

The exemplary embodiments of the present disclosure can also be described as follows:
According to an aspect of the present disclosure, a display device includes an active area in which a plurality of sub pixels is disposed, a first non-active area which encloses the active area, a bending area which extends from the first non-active area, and a second non-active area which extends from the bending area, the display device includes a first substrate disposed in the active area and the first non-active area, a second substrate which is disposed in the second non-active area and is spaced apart from the first substrate and a plurality of insulating layers which is disposed on the first substrate and the second substrate and extends to the bending area, wherein at least a part of the plurality of insulating layers includes a plurality of first holes disposed along a bending direction in the bending area.
The display device further includes a micro coating layer which is disposed above and below the plurality of insulating layers in the bending area.
The micro coating layer may be disposed so as to be filled in the plurality of first holes.
The first substrate and the second substrate may be glass substrates.
A planar shape of the plurality of first holes may be a square or a rectangle.
The display device further includes a link line which is disposed in a center portion of the bending area and supplies a signal to the plurality of sub pixels, wherein the plurality of first holes is disposed in both sides of the center portion in which the link line is disposed in the bending area.
The plurality of first holes may be disposed to be spaced apart in a direction intersecting the bending direction to be parallel.
Both ends of each of the plurality of first holes may be located in a boundary of the bending area.
The plurality of first holes may have the same length and may be disposed to be staggered from each other.

The plurality of first holes may be disposed to be spaced apart from each other in the bending direction.
The plurality of first holes may have different lengths and may be disposed to be staggered from each other.
The plurality of insulating layers may further include a plurality of second holes disposed along the bending direction in the first non-active area and the second non-active area adjacent to the bending area.
The plurality of insulating layers may include a first insulating layer, a second insulating layer on the first insulating layer and a bank layer on the second insulating layer, and the plurality of second holes is disposed in the first insulating layer, the second insulating layer, and the bank layer.
The plurality of first holes may be disposed in the first insulating layer, the second insulating layer, and the bank layer.
The plurality of first holes may be disposed in the second insulating layer and the bank layer.
Each of the first substrate and the second substrate may have a side surface adjacent to the bending area which is inclined or concave.
According to another aspect of the present disclosure, a display device includes a plurality of insulating layers which includes an active area in which a plurality of sub pixels is disposed, a first non-active area which encloses the active area, a bending area which extends from the first non-active area, and a second non-active area which extends from the bending area, a first substrate disposed below the plurality of insulating layers in the active area and the first non-active area, a second substrate which is disposed below the plurality of insulating layers in the second non-active area and is spaced apart from the first substrate, a plurality of first holes which is disposed in at least a part of the plurality of insulating layers along a bending direction in the bending area and a micro coating layer which is disposed above and below the plurality of insulating layers in the bending area and is filled in the plurality of first holes.
A planar shape of the plurality of first holes may be a square or a rectangle and the plurality of first holes may be disposed to be spaced apart from each other in the direction intersecting the bending direction to be parallel and may be disposed to be staggered.
The plurality of insulating layers may further include a plurality of second holes disposed along the bending direction in the first non-active area and the second non-active area adjacent to the bending area.
The plurality of insulating layers may include a first insulating layer, a second insulating layer on the first insulating layer and a bank layer on the second insulating layer, and the plurality of first holes is disposed in the first insulating layer, the second insulating layer, and the bank layer and the plurality of second holes is disposed in the first insulating layer, the second insulating layer, and the bank layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure.

The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device
which includes an active area in which a plurality of sub pixels is disposed, a first non-active area which encloses the active area, a bending area which extends from the first non-active area, and a second non-active area which extends from the bending area, the display device comprising:
a first substrate disposed in the active area and the first non-active area;
a second substrate which is disposed in the second non-active area and is spaced apart from the first substrate; and
a plurality of insulating layers which is disposed on the first substrate and the second substrate and extends to the bending area,
wherein at least a part of the plurality of insulating layers includes a plurality of first holes disposed along a bending direction in the bending area.

2. The display device according to claim 1, further comprising:
a micro coating layer which is disposed above and below the plurality of insulating layers in the bending area.

3. The display device according to claim 2, wherein the micro coating layer further comprises a portion which is disposed so as to be filled in the plurality of first holes.

4. The display device according to claim 1, wherein the first substrate and the second substrate are glass substrates.

5. The display device according to claim 1, wherein a planar shape of the plurality of first holes is a square or a rectangle.

6. The display device according to claim 1, further comprising:
a link line which is disposed in a center portion of the bending area and supplies a signal to the plurality of sub pixels,
wherein the plurality of first holes is disposed in both sides of the center portion in which the link line is disposed in the bending area.

7. The display device according to claim 1, wherein the plurality of first holes is disposed to be spaced apart in a direction intersecting the bending direction to be parallel.

8. The display device according to claim 7, wherein both ends of each of the plurality of first holes are located in a boundary of the bending area.

9. The display device according to claim 7, wherein the plurality of first holes has the same length and is disposed to be staggered from each other.

10. The display device according to claim 7, wherein the plurality of first holes is disposed to be spaced apart from each other in the bending direction.

11. The display device according to claim 10, wherein the plurality of first holes has different lengths and is disposed to be staggered from each other.

12. The display device according to claim 1, wherein the plurality of insulating layers further includes a plurality of second holes disposed along the bending direction in the first non-active area and the second non-active area adjacent to the bending area.

13. The display device according to claim 12, wherein the plurality of insulating layers includes:
a first insulating layer;
a second insulating layer disposed on the first insulating layer; and
a bank layer disposed on the second insulating layer, and
the plurality of second holes is disposed in the first insulating layer, the second insulating layer, and the bank layer.

14. The display device according to claim 13, wherein the plurality of first holes is disposed in the first insulating layer, the second insulating layer, and the bank layer.

15. The display device according to claim 13, wherein the plurality of first holes is disposed in the second insulating layer and the bank layer.

16. The display device according to claim 1, wherein each of the first substrate and the second substrate has a side surface adjacent to the bending area which is inclined or concave.

17. A display device, comprising:
a plurality of insulating layers which includes an active area in which a plurality of sub pixels is disposed, a first non-active area which encloses the active area, a bending area which extends from the first non-active area, and a second non-active area which extends from the bending area;
a first substrate disposed below the plurality of insulating layers in the active area and the first non-active area;
a second substrate which is disposed below the plurality of insulating layers in the second non-active area and is spaced apart from the first substrate;
a plurality of first holes which is disposed in at least a part of the plurality of insulating layers along a bending direction in the bending area; and
a micro coating layer comprising a portion which is disposed above and below the plurality of insulating layers in the bending area and comprising another portion which is filled in the plurality of first holes.

18. The display device according to claim 1, wherein a plurality of first holes has a planar shape that is square or rectangular, is spaced apart from one another in a direction intersecting the bending direction so as to be parallel, and is disposed in a staggered pattern.

19. The display device according to claim 18, wherein the plurality of insulating layers further includes a plurality of second holes disposed along the bending direction in the first non-active area and the second non-active area adjacent to the bending area.

20. The display device according to claim 19, wherein the plurality of insulating layers includes:
a first insulating layer;
a second insulating layer disposed on the first insulating layer; and
a bank layer disposed on the second insulating layer, and
the plurality of first holes is disposed in the first insulating layer, the second insulating layer, and the bank layer and the plurality of second holes is disposed in the first insulating layer, the second insulating layer, and the bank layer.
